(19) United States
(12) Patent Application Publication
(10) Pub. No.: US 2017/0138998 A1
(43) Pub. Date: May 18, 2017

(54) Testing Device for Connection Interface and Related Testing Methods

(71) Applicant: MEDIATEK INC., Hsin-Chu (TW)

(72) Inventors: Chih-Chun Lin, Taipei City (TW); Chun-Chih Fan, Hsinchu County (TW)

(21) Appl. No.: 15/299,484

(22) Filed: Oct. 21, 2016

Related U.S. Application Data
(60) Provisional application No. 62/255,547, filed on Nov. 16, 2015.

(51) Int. Cl. G01R 31/04; G08B 5/36

(52) U.S. Cl. CPC G01R 31/043; G08B 5/36

(57) ABSTRACT

A testing device for a connection interface of an electronic device includes an interface module, comprising a plurality of pins for coupling to the connection interface of the connection interface; and a testing circuit, comprising at least one of a conducting path between a first pin and a second pin among the plurality of pins, a visualized module coupled to a third pin of the plurality of pins, and an impedance coupled to a fourth pin of the plurality of pins.

### CROSS REFERENCE TO RELATED APPLICATIONS

This application claims the benefit of U.S. Provisional Application No. 62/255,547 filed on Nov. 16, 2016, the contents of which are incorporated herein in their entirety.

### BACKGROUND

The present invention relates to a testing device and related testing methods, and more particularly, to a testing device for a connection interface of an electronic device and related testing methods.

Universal serial bus, USB, is an industry standard defining specifications of connectors and communication protocols used in interfaces between computers and external electronic devices. In July 2013, a latest USB 3.1 standard was released to replace the former USB 3.0 standard. Based on specifications of the USB 3.1 standard, USB type-C, a new connector structure, was published. Different from type-A or type-B connector, the type-C connector is reversible and comprises 24 pins, which consist of 4 pairs of SuperSpeed USB serial data pins, 2 differential pairs of USB 2.0 serial data pins, 2 configuration channel pins, 2 sideband use pins, 4 pairs of power and ground pins.

Although the number of pins in the type-C connector significantly increases, the cross-sectional area of the type-C connector remains approximate to that of a micro-USB connector comprising only 5 pins. This increases the difficulty of manufacture and integration. Because of the type-C connector's compact structure, an electronic device with the type-C connector may encounter problems during mass production. For example, a solder empty problem may occur when the type-C connector is configured on a circuit board of the electronic device by surface mount technology (SMT), resulting in failure of connecting the type-C connector and the circuit board. The yield of the electronic device with the type-C connectors is therefore decreased. Further, conventional methods of detecting the defect electronic device with the solder empty problem, such as utilizing X-ray or customized laser detection equipment to check the connections between the type-C connector and the circuit board, are time consuming and largely increase a manufacture cost of the electronic device. Thus, how to efficiently detect the defect electronic device without significantly increasing the manufacture cost becomes a topic to be discussed.

### SUMMARY

In order to solve the above issue, the present invention provides a testing device for a connection interface of the electronic device and related testing methods.

In an aspect, the present invention discloses a testing device for a connection interface of an electronic device. The testing device comprises an interface module, comprising a plurality of pins for coupling to the connection interface of the connection interface; and a testing circuit, comprising at least one of a conducting path between a first pin and a second pin among the plurality of pins, a visualized module coupled to a third pin of the plurality of pins, and an impedance coupled to a fourth pin of the plurality of pins.

In another aspect, the present invention discloses a testing method for an electronic device with a connection interface coupled to a testing device. The testing method comprises executing a testing application, to perform at least one of transmitting and receiving testing data through a transmission pair of the connection interface and a conducting path of the testing device and checking a function of the transmission pair according to the received testing data; providing a first predefined voltage to a power pin of the connection interface coupled to a first visualized module of the testing device; acquiring a voltage of a configuration channel pin of the connection interface coupled to an impedance of the testing device and checking the function of the configuration channel pin according to the acquired voltage; and asserting a voltage of a transmission pin of the connection interface coupled to a second visualized module of the testing device to a second predefined voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a testing device 10 according to an example of the present invention.

FIG. 2 is a schematic diagram of a testing circuit according to an example of the present invention.

FIG. 3 is a schematic diagram of a testing circuit according to an example of the present invention.

FIG. 4 is a schematic diagram of a testing circuit according to an example of the present invention.

FIG. 5 is a schematic diagram of a testing circuit according to an example of the present invention.

FIG. 6 is a schematic diagram of a testing circuit according to an example of the present invention.

FIG. 7 is a flowchart of a testing method according to an example of the present invention.

FIG. 8 is a flowchart of a testing method according to an example of the present invention.

FIG. 9 is a flowchart of a testing method according to an example of the present invention.

FIG. 10 is a flowchart of a testing method according to an example of the present invention.

### DETAILED DESCRIPTION

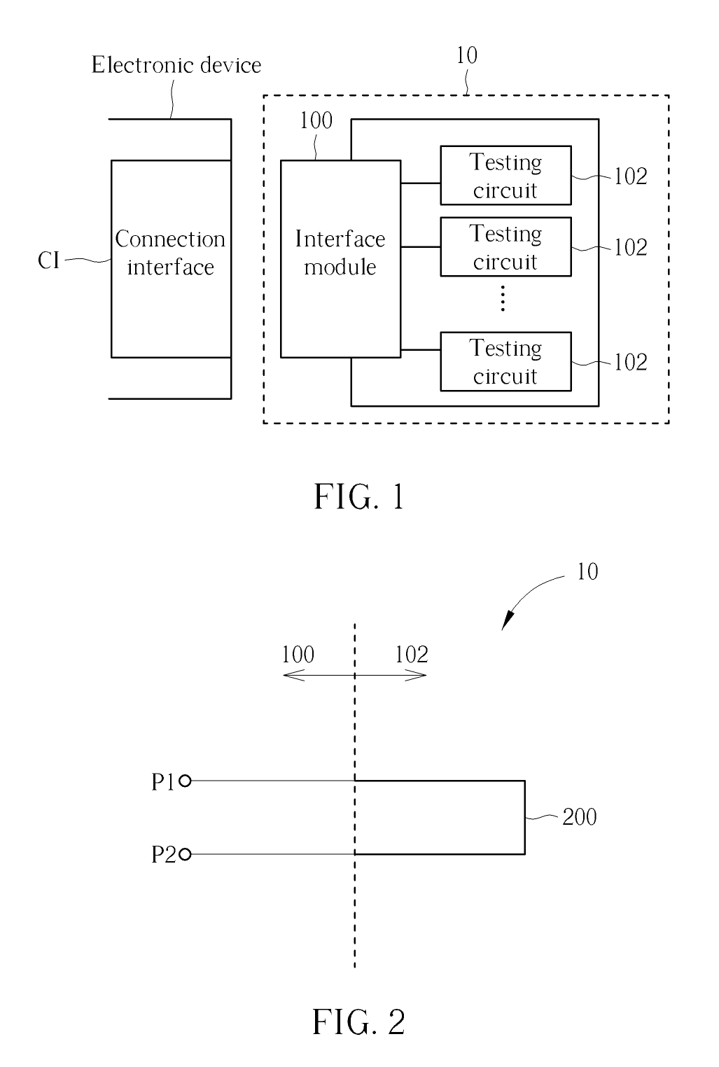

Please refer to FIG. 1, which is a schematic of a testing device 10 according to an example of the present invention. The testing device 10 may be a dongle capable of attaching to an electronic device through a connection interface of a data communication standard, such as a USB 3.1 connection interface, for testing functions of the connection interface of the electronic device (e.g. testing whether connections between the connection interface and the electronic device are successfully established). As shown in FIG. 1, the testing device 10 comprises an interface module 100 and a plurality of testing circuits 102. The interface module 100 comprises a plurality of pins (not shown in FIG. 1) and is able to connect to the connection interface of the electronic device. For example, the interface module 100 may be a male of female socket of the data communication standard and is not limited herein. The plurality of testing circuits 102 are coupled to at least one of the pins of the interface module 100. In an example, the interface module 100 and the testing circuits 102 are configured on a substrate and are connected by metal traces on the substrate. The testing circuits 102 are utilized to allow the electronic device to test the functions of the connection interface or to generate visualized signals to indicate testing results of the connection interface. Via adopting the testing device 10, a user is able to efficiently test the connection interface and the manufacture cost of the electronic device is decreased because of a low manufacture cost of the testing device 10.

In details, a design of each testing circuit 102 varies with functions of the pins coupled to each testing circuit 102. In an example, one of the testing circuits 102 may form a conducting path between two pins of the interface module 100. Please refer to FIG. 2, which is a schematic diagram of a testing circuit 102 according to an example of the present invention. In FIG. 2, the testing circuit 102 forms a conducting path 200 between pins P1 and P2 of the interface module 100. When the interface module 100 is attached to the connection interface CI, the pins P1 and P2 are designed to connect to a transmission pair of the connection interface CI, to transmit and to receive data signals from the electronic device. In an example, the pins P1 and P2 are coupled to one of the transmission pairs defined to transmit signals of USB 3.1 data buses in a USB type-C interconnect. For example, the pins P1 and P2 may be coupled to USB 3.1 data buses pins TX1+ and RX1+, TX1− and RX1−, TX2+ and RX2+, or TX2− and RX2− in the USB type-C interconnect (i.e. a male of female socket). In another example, the pins P1 and P2 are coupled to pins whose functions are defined by the user. For example, the pins P1 and P2 may be coupled to Sideband Use (SBU) signal pins SBU1 and SBU2 in the USB type-C interconnect.

When the testing device 10 is attached to the electronic device, the electronic device executes a testing application and enters a loopback mode to transmit testing data and to receive the testing data through the pins P1, P2 and the conducting path 200, to check the transmission pair of the connection interface CI coupled to the pins P1 and P2. In an example, the electronic device determines that the conducting paths of the transmission pair of the connection interface CI coupled to the pins P1 and P2 are successfully established if the data error rate of the transmission of the testing data is below an error threshold. After acquiring testing results, the electronic device may display information of the testing results on a display of the electronic device, to allow the user to perform corresponded procedures.

Note that, the electronic device needs to define the functions of pins coupled to the pins P1 and P2 to be transmitting/receiving data when the functions of the pins coupled to the pins P1 and P2 are defined by the user. For example, the electronic device may connect the pins coupled to the pins P1 and P2 to a communication module (e.g. a Universal Asynchronous Receiver/Transmitter (UART)) of the electronic device and control the communication module to transmit and to receive the testing data via the conducting path 200 consisting of the pins P1, P2, to determine whether the data transmission works normally.

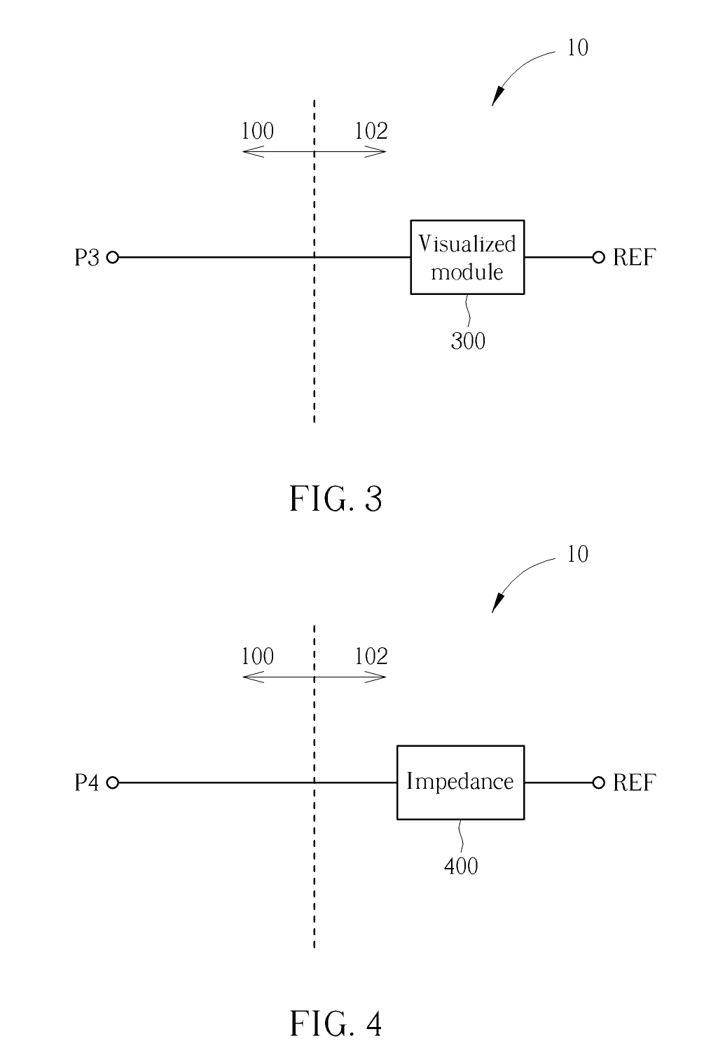

In an example, the testing circuit 102 comprises a visualized module capable of generating visualized signal according to a voltage provided by the pin coupled to the testing circuit 102. Please refer to FIG. 3, which is a schematic diagram of the testing circuit 102 according to an example of the present invention. As shown in FIG. 3, the testing circuit 102 comprises a visualized module 300 coupled between a pin P3 of the interface module 100 and a reference node REF (e.g. the ground). In this example, the pin P3 of the interface module 100 is coupled to the pin of the connection interface CI defined to provide a predefined voltage when attaching to the connection interface CI. For example, the pin P3 may be coupled to a USB power pins VBUS in the USB type-C interconnect that provides a power voltage.

When the testing device 10 is attached to the electronic device, the electronic device executes a testing application to provide the predefined voltage at the pin coupled to the pin P3. If the pin of the connection interface CI coupled to the pin P3 is correctly configured on the electronic device, the visualized module 300 is activated by the predefined voltage and accordingly generates the visualized signal, to inform the user that the pin coupled to the pin P3 works normally; otherwise, the voltage provided by the pin P3 may not turn on the visualized module 300 to generate the visualized signal. The user therefore can check the function of the pin coupled to the pin P3 when the testing device 10 is attached to the electronic device according to whether the visualized module generates the visualized signal.

According to different testing applications and design concepts, the visualized module 300 may be realized by various methods. In an example, the visualized module 300 comprises a light emitting diode (LED). An anode of the LED is coupled to the pin P3 and a cathode of the LED is coupled to the reference node REF. Under such a condition, the LED emits light when the voltage provided by the pin P3 exceeds a threshold voltage of the LED. In another example, the visualized module 300 comprises a counter circuit that is powered by the pin P3. When the pin P3 provides the predefined voltage to the counter circuit, the counter circuit starts counting and displays a varying number via a display component (e.g. a seven-segment display) of the counter circuit.

In an example, the testing circuit 102 comprises impedance coupled to a pin of the interface module 100 to provide a matching loading. Please refer to FIG. 4, which is a schematic diagram of the testing circuit 102 according to an example of the present invention. In FIG. 4, the testing circuit 102 comprises an impedance 400 coupled between a pin P4 and a reference node REF. The pin P4 is designed to connect to the pin defined to determine a configuration relationship (e.g. a host-to-device relationship) between the electronic device and the device connected to the electronic device via the connection interface CI. For example, the pin P4 maybe coupled to a configuration channel pin CC1 or CC2 of the USB type-C interconnect when the testing device 10 is attached to the electronic device with the connection interface CI.

Note that, the reference node REF maybe coupled to the ground (e.g. the pin of the interface module 100 coupled to a ground pin of the connection interface CI) or a pin providing a predefined voltage (e.g. the pin coupled to the power pin of the connection interface CI) and the impedance value of the impedance 400 changes with a voltage of the reference node REF. In the example of the connection interface CI being the USB type-C interconnect, a resistance of the impedance 400 is 56 k ohms when the reference node is coupled to the pin designed to connect the USB power pin VBUS and is 5.1 k ohms when the reference node is coupled to the pin designed to connect the ground.

When the testing device 10 is attached to electronic device via the connection interface CI, the electronic device executes a testing application and begins detecting a voltage at the pin P4 to determine the configuration relationship between the electronic device and the testing device 10. If the pin of the connection interface CI coupled to the pin P4 is correctly configured on the electronic device, the electronic device is able to determine the configuration relationship successfully according to the acquired voltage; otherwise, the electronic device cannot determine the configuration relationship. The electronic device may display the determined results of the configuration relationship on the display component of the electronic device to indicate the testing result and the user therefore can check the function of the pin of the connection interface CI coupled to the pin P4 according to the determined results of the configuration relationship.

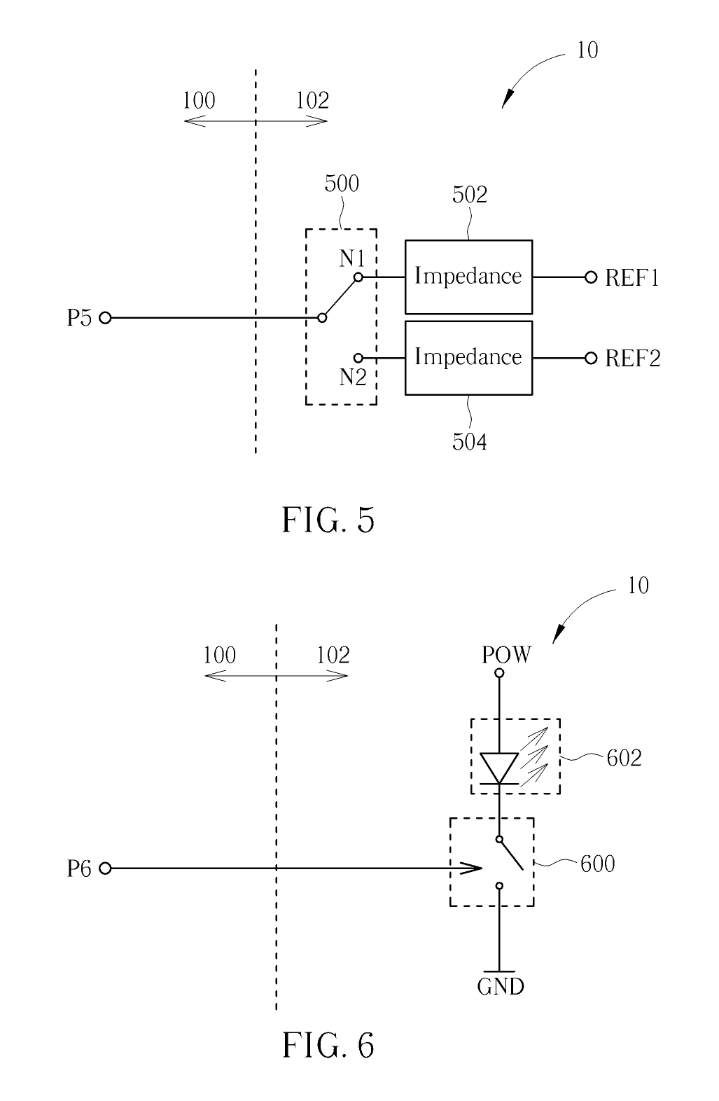

Please refer to FIG. 5, which is a schematic diagram of the testing circuit 102 according to an example of the present invention. In FIG. 5, the testing circuit 102 comprises a switch 500, impedances 502 and 504. The switch 500 is utilized to conduct either a pin P5 and a node N1 or the pin p5 and a node N2. In an example, the switch 500 is a dip switch and is manually controlled by the user. In another example, the switch 500 is controlled by a control signal (not shown in FIG. 5) generated by other circuits (not shown) of the testing device 10. The impedance 502 is coupled between the node N1 and a reference node REF1, and the impedance 504 is coupled between the node N2 and a reference node REF2. The impedance values of the impedances 502 and 504 are designed according to the voltages of the reference nodes REF1 and REF2. In an example, the impedance value of the impedance 502 is 56 k ohms and the impedance value of the impedance 504 is 5.1 k ohms when the reference node N1 is coupled to the power pins of the connection interface CI and the reference node N2 is coupled to the ground pin of the connection interface CI.

When the electronic device executes the testing application to check the function of the pin coupled to the pin P5, the switch 500 conducts either the pin P5 and the node N1 or the pin P5 and the node N2. Under such a condition, the operation principles of the electronic device checking the function of the pin coupled to the pin P5 are similar to those of the electronic device checking the function of the pin coupled to the pin P4 and are not narrated herein for brevity.

Please refer to FIG. 6, which is a schematic diagram of a testing circuit 102 according to an example of the present invention. The testing circuit 102 shown in FIG. 6 comprises a switch 600 and a visualized circuit 602. The switch 600 is coupled between the ground GND and the visualized circuit 602 and is controlled by a signal of a pin P6. The pin P6 may be designed to connect to a transmission pin of the connection interface CI defined to transmit or to receive data signals (e.g. one of USB 2.0 data buses pins D+ and D− in the USB 3.1 type-C interconnect). In an example, the switch 600 comprises an N-type Metal-Oxide-Semiconductor Field-Effect Transistor (NMOS), wherein a gate of the NMOS is coupled to the pin P6, a source of the NMOS is coupled to the ground GND, and a drain of the NMOS is coupled to the visualized circuit 602. The visualized circuit 602 comprises a LED, wherein the anode of the LED is coupled to a power POW and the cathode of the LED is coupled to the switch 600. Note that, the power POW and the ground GND may be provided by the power pin and the ground pin of the connection interface CI and are not limited herein.

When the testing device 10 is attached to the electronic device, the switch 600 receives the signal from the pin P6. The electronic device executes a testing application to assert a signal of the transmission pin of the connection interface CI coupled to the pin P6 to a high-logic level, to control the switch 600 to conduct the connection between the cathode of the LED and the ground GND. If the transmission pin of the connection interface CI coupled to the pin P6 is correctly configured on the electronic device, the switch 600 conducts the connection and the LED emits light; otherwise, the switch 600 disconnects the connection and the LED doesn't emit light. The user therefore can check the function of the pin of the connection interface CI coupled to the pin P6 according to whether the LED shines.

Note that, the visualized circuit 602 may be realized by different methods. For example, the LED may be replaced by a counter circuit. When the switch 600 is conducted by the signal of the pin P6, the counter circuit begins counting and generates visualized signal to display varying number. Thus, the user checks the function of the pin of the connection interface CI coupled to the pin P6 according whether the varying number is displayed.

According to different application and designed concepts, those with ordinary skill in the art may observe appropriate alternations and modifications. For example, one of the testing circuits 102 shown in FIG. 1 may comprise multiple of the testing circuits 102 shown in FIGS. 2-6, to check multiple pins of the connection interface CI simultaneously.

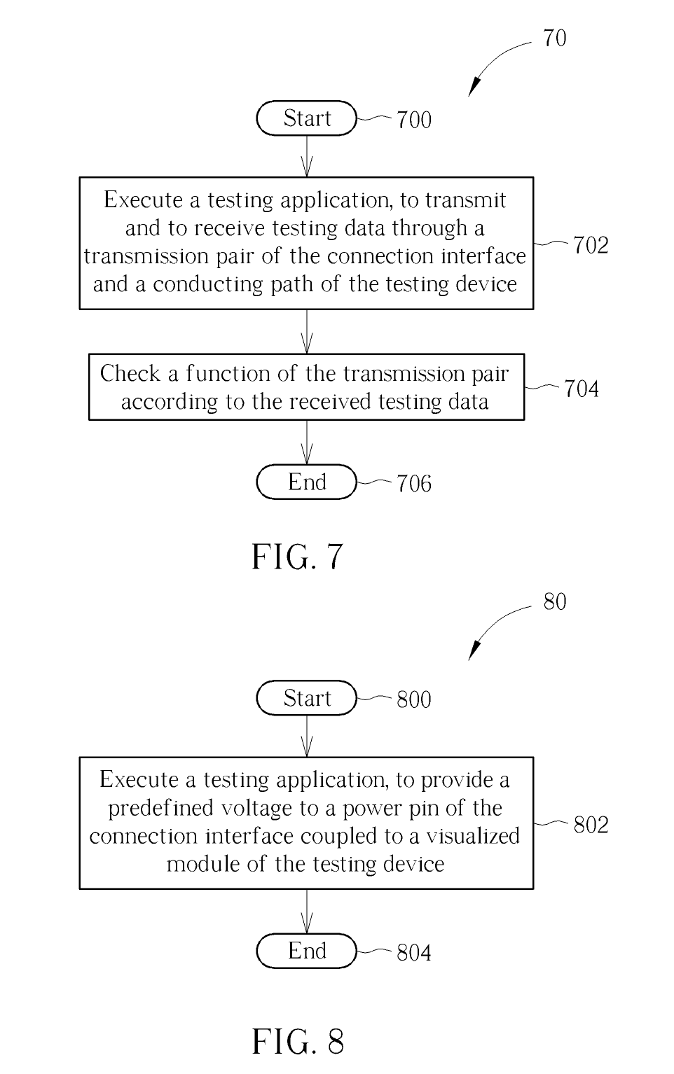

The process of the electronic device performing the testing application to check the configuration statuses of the pins P1 and P2 can be summarized into a testing method 70 shown in FIG. 7. The testing method 70 may be compiled into a program code stored in a storage unit and executed by a computing unit, such as a central processing unit (CPU) or an testing application-specific integrated circuit (ASIC). The testing method 70 is utilized in an electronic device with a connection interface of a communication standard (e.g. a USB 3.1 type-C interconnect) when a testing device is attached to the electronic device via the connection interface and comprises the following steps:
Step 700: Start.
Step 702: Execute a testing application, to transmit and to receive testing data through a transmission pair of the connection interface and a conducting path of the testing device.
Step 706: Check a function of the transmission pair according to the received testing data.
Step 708: End.

According to the testing method 70, the electronic device performs a testing application when the testing device is attached to the electronic device via the connection interface, to check a function of a transmission pair of the connection interface (e.g. USB 3.1 data buses pins TX1+ and RX1+, TX1− and RX1−, TX2+ and RX2+, or TX2− and RX2− of the USB type-C interconnect or sideband use pins SBU1 and SBU2 coupled to a communication module of the electronic device). When operating the testing application, the electronic device may enter a loopback mode to transmit and to receive testing data via the transmission pair of the connection interface. When attached to the electronic device via the connection interface, the testing device forms a conducting path between pins of the transmission pair. Under such a condition, an error rate of the transmission of the testing data supposes to be low if the function of the transmission pair works normally. Thus, the electronic device calculates the error rate according to the received testing data as a reference of checking the function of the transmission pair. If the error rate exceeds an error threshold, the electronic device determines that the transmission pair works abnormally; otherwise, the electronic device determines that the transmission pair works normally. The electronic device may record the determined results or display the determined results on a display component of the electronic device to inform the user to perform corresponded procedures.

The process of the electronic device performing the testing application to check the configuration statuses of the pin P3 can be summarized into a testing method 80 shown in FIG. 8. The testing method 80 may be compiled into a program code stored in a storage unit and executed by a computing unit. The testing method 80 is utilized in an electronic device with a connection interface of a communication standard (e.g. a USB 3.1 type-C interconnect) when a testing device is attached to the electronic device via the connection interface and comprises the following steps:
Step 800: Start.
Step 802: Execute a testing application, to provide a predefined voltage to a power pin of the connection interface coupled to a visualized module of the testing device.
Step 804: End.

According to the testing method 80, the electronic device executes a testing application when the testing device is attached to the electronic device via the connection interface, to check a function of a power pin of the connection interface (e.g. an USB power pins VBUS in the USB type-C interconnect). When operating the testing application, the electronic device provides a predefined voltage to the power pin of the connection interface that is coupled to a visualized module of the testing device. If receiving the predefined voltage, the visualized module is activated by the predefined voltage and generates a visualized signal to indicate that the predefined voltage is received. In an example, the visualize module comprises a LED and the LED emits light when receiving the predefined voltage. In another example, the visualize module comprises a counter circuit and the counter circuit display a varying number via a display component of the testing device when receiving the predefined voltage. Thus, the user can check the function of the power pin according to whether the visualized signal is generated.

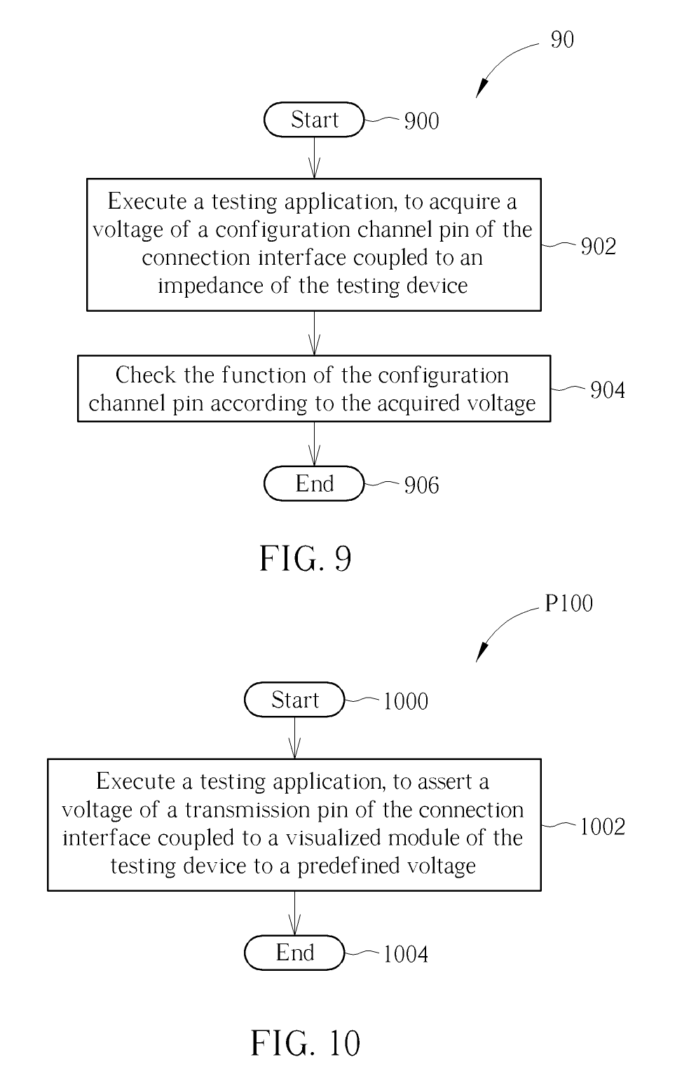

The process of the electronic device performing the testing application to check the configuration statuses of the pin P4 can be summarized into a testing method 90 shown in FIG. 9. The testing method 90 may be compiled into a program code stored in a storage unit and executed by a computing unit. The testing method 90 is utilized in an electronic device with a connection interface of a communication standard (e.g. a USB 3.1 type-C interconnect) when a testing device is attached to the electronic device via the connection interface and comprises the following steps:
Step 900: Start.
Step 902: Execute a testing application, to acquire a voltage of a configuration channel pin of the connection interface coupled to an impedance of the testing device.
Step 904: Check the function of the configuration channel pin according to the acquired voltage.
Step 906: End.

According to the testing method 90, the electronic device executes a testing application when the testing device is attached to the electronic device via the connection interface, to check a function of a configuration channel pin of the connection interface (e.g. a configuration channel pin CC1 or CC2). Because a voltage of the configuration channel pin changes with the impedance coupled to the configuration channel pin, the electronic device acquires the voltage of the configuration channel pin and accordingly checks the function of the configuration channel pin. For example, the electronic device may determine a host-to-device relationship according to the acquired voltage. The electronic device may check the function of the configuration channel pin according to whether the host-to-device relationship is able to be determined. The electronic device may display the determined results on a display component of the electronic device to indicate the determined results.

The process of the electronic device performing the testing application to check the configuration statuses of the pin P6 can be summarized into a testing method P100 shown in FIG. 10. The testing method P100 may be compiled into a program code stored in a storage unit and executed by a computing unit. The testing method P100 is utilized in an electronic device with a connection interface of a communication standard (e.g. a USB 3.1 type-C interconnect) when a testing device is attached to the electronic device via the connection interface and comprises the following steps:
Step 1000: Start.
Step 1002: Execute a testing application, to assert a voltage of a transmission pin of the connection interface coupled to a visualized module of the testing device to a predefined voltage.
Step 1004: End.

According to the testing method P100, the electronic device executes a testing application when the testing device is attached to the electronic device via the connection interface, to check a function of a transmission pin of the connection interface, such as a USB 2.0 data buses pin D+ or D− in a USB 3.1 type-C interconnect. The transmission pin is coupled to a visualized module of the testing device and the electronic device asserts a voltage of the transmission pin to a predefined voltage. If receiving the asserted voltage, the visualized module generates a visualized signal to indicate that the function of the transmission pin works normally; otherwise, the testing device does not generate the visualized signal. In an example, the visualized module is controlled by a switch. When the voltage of the transmission pin is asserted to the predefined voltage, the switch is turned on to make the visualized module generate the visualized signal. The user therefore can check the function of the transmission pin based on the visualized signal.

Note that, the testing methods 70, 80, 90 and P100 may be combined into a single testing method, to simultaneously check the functions of multiple pins in the connection interface of the electronic device. Or, the electronic device may selectively execute the testing methods 70, 80, 90 and/or P100 based on requirements of the user.

To sum up, the above example provides the testing device for the electronic device with the connection interface of the communication standard and the related testing methods. Via adopting the testing device and the related testing methods, the user is able to efficiently test functions of the connection interface and the manufacture cost of the electronic device is decreased because of a low manufacture cost of the testing device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A testing device for a connection interface of an electronic device, comprising:
an interface module, comprising a plurality of pins for coupling to the connection interface of the connection interface; and
a testing circuit, comprising at least one of a conducting path between a first pin and a second pin among the plurality of pins, a visualized module coupled to a third pin of the plurality of pins, and an impedance coupled to a fourth pin of the plurality of pins.

2. The testing device of claim 1, wherein the first pin and the second pin are coupled to a transmission pair of the connection interface when the testing device is attached to the connection interface.

3. The testing device of claim 1, wherein the visualized module generates a visualized signal according to a first voltage provided by the third pin.

4. The testing device of claim 3, wherein the visualized module comprises a light emitting diode (LED), an anode of the LED is coupled to the third pin, and a cathode of the LED is coupled to a reference node.

5. The testing device of claim 3, wherein the visualized module comprises a counter circuit.

6. The testing device of claim 3, wherein the visualized module comprises a visualized circuit coupled between the third pin and a ground.

7. The testing device of claim 3, wherein the visualized module comprises:
a visualized circuit, coupled between a first node and a fifth pin of the plurality of pins providing a second voltage; and
a switch, for controlling the connection between the first node and a ground according to the first voltage provided by the third pin.

8. The testing device of claim 1, wherein the impedance is coupled between the fourth pin and a reference node.

9. The testing device of claim 8, wherein the reference node is a ground.

10. The testing device of claim 8, wherein the reference node is coupled to a sixth pin of the plurality of pins providing a third voltage.

11. The testing device of claim 1, wherein the impedance comprises:
a switch, for conducting a first conducting path between the fourth pin and a second node or a second conducting path between the fourth pin and a third node;
a first impedance, coupled between the second node and a seventh pins of the plurality of pins providing a forth voltage; and
a second impedance, coupled between the third node and a ground.

12. A testing method for an electronic device with a connection interface coupled to a testing device, the testing method comprising:
executing a testing application, to perform at least one of transmitting and receiving testing data through a transmission pair of the connection interface and a conducting path of the testing device and checking a function of the transmission pair according to the received testing data; providing a first predefined voltage to a power pin of the connection interface coupled to a first visualized module of the testing device; acquiring a voltage of a configuration channel pin of the connection interface coupled to an impedance of the testing device and checking the function of the configuration channel pin according to the acquired voltage; and asserting a voltage of a transmission pin of the connection interface coupled to a second visualized module of the testing device to a second predefined voltage.

13. The testing method of claim 12, wherein the step of checking the function of the transmission pair according to the received testing data comprises:
calculating an error rate according to the received testing data; and
check the function of the transmission pair according to the error rate and an error threshold.

14. The testing method of claim 12, wherein the first visualized module generates a visualized signal when receiving the first predefined voltage.

15. The testing method of claim 12, wherein the voltage of the transmission pin conducts a switch of the second visualized module when asserted to the second predefined voltage to make the second visualized module generate a visualized signal.
